(19) United States
(12) Patent Application Publication
(10) Pub. No.: US 2005/0108875 A1
(43) Pub. Date: May 26, 2005

(54) Methods for making vertical electric feed through structures usable to form removable substrate tiles in a wafer test system

(76) Inventors: Gaetan L. Mathieu, Livermore, CA (US); Igor Y. Khandros, Orinda, CA (US); Carl Reynolds, Pleasanton, CA (US)

Correspondence Address: FLIESLER MEYER, LLP, FOUR EMBARCADERO CENTER, SUITE 400, SAN FRANCISCO, CA, 94111, US

(21) Appl. No.: 10/723,263

(22) Filed: Nov. 26, 2003

(51) Int. Cl. H05K 3/30; H01R 43/00

(52) U.S. Cl. 29/852; 29/837; 29/884

(57) ABSTRACT

Methods are provided for making vertical feed through electrical connection structures in a substrate or tile. The vertical feed throughs are configured to make the tile attachable and detachable as a layer between other substrates. For example, the tile with vertical feedthroughs can form an easily detachable space transformer tile in a wafer test system. The vertical feed through paths are formed with one end of each feed through hole permanently encapsulating a first electrical contact, and a second end supporting another pluggable and unpluggable electrical probe contact. Decoupling capacitors can be further plugged into holes formed in close proximity to the vertical feed through holes to increase performance of the decoupling capacitor.

### BACKGROUND

1. Technical Field

The present invention relates to methods for making vertical electrical feed through connections in a substrate. More particularly, the present invention relates to methods for making vertical feed throughs to create an easily detachable substrate, or space transformer for a wafer test system.

2. Related Art

One method of making a vertical electrical connection is to use a plated through hole. Plated through holes have been developed to connect electrical components on different layers of multiple layer semiconductor structures, such as layers of a printed circuit board (PCB). Plated through holes are further used to form interconnect elements enabling one PCB to be connected to components on a separate PCB or other discrete electrical components.

With a single multilayered PCB, the plated through holes formed in the PCB during manufacture serve to provide electrical coupling between circuits on the different layers. Fabrication of a PCB typically includes drilling a hole through a substrate made up of the layers, electrolytically plating the hole and conductive areas on the PCB layers with a metallic substance such as copper to form the plated through hole. A first circuit pattern is then formed in the conductive area on a first PCB layer and a second circuit pattern on a second PCB layer such that the plated through hole electrically couples the first circuit pattern to the second circuit pattern.

Plated through holes were developed for layered PCBs because it was generally found impractical due to the labor and cost involved to form multiple connections by physically inserting a conductive element (such as a wire) in a hole and then connecting the element to two circuits by soldering or other means. As described above, the usual method of forming plated through holes is to plate the circuits formed on the PCB layers and the through hole connections simultaneously so that the through hole connection is made as an integral part of circuit elements on different levels of the PCB without significant added labor or cost.

For two separate PCBs having electrical components to be connected after manufacture, or one PCB to be connected to a separate discrete electrical component, an insertable conductive element (such as a wire) forming a connector is still typically used. Such connectors can be formed by inserting connector pins into plated through holes of separate PCBs and soldering them in place. Such plated through holes provide connections between the pins and conductive regions on the separate PCBs or discrete components. An example of a technique of manufacturing PCBs with connector pins provided in plated through holes is described in U.S. Pat. No. 6,521,842, entitled “Hybrid Surface Mount And Pin Thru Hole Circuit Board.”

Recently PCBs have been used to support multiple resilient wires or probes to form probe cards used in temporarily connecting to electrical components, such as on semiconductor wafers for testing. It would be desirable to provide a method for efficiently manufacturing such multiple temporary connection elements for probe cards.

### SUMMARY

In accordance with the present invention, methods are provided for making vertical feed through structures configured to provide an easily attachable and detachable substrate. The vertical feed through can be formed similar to plated through holes configured to support connectors or probes. When formed, the vertical feed through structures described include a hole or via with one portion of the feed through hole permanently encapsulating an electrical contact, and another portion of the hole, which may be plated through, containing a pluggable and unpluggable electrical contact element.

In one embodiment, the vertical feed through structure includes a substrate tile with feed through holes, one end of each hole including an insert cap providing an electrical contact, and another end of each hole being available for insertion of a probe connected to another substrate layer. The insert cap is permanently formed into a hole as part of the tile by one of a number of procedures including injection molding the tile material around the cap, pressing the cap into a hole in preformed material, or soldering the cap into preformed plated through holes. The substrate for the tile can be an organic material such as epoxy, or a ceramic material such as Low Temperature Cofired Ceramic (LTCC) or High Temperature Cofired Ceramic (HTCC). For ceramics which are fired after insertion of the cap, it is desirable that thermal expansion does not occur in the x-y plane of the tile to enable alignment of the cap with electrical contacts on another substrate. The cap can be configured to support a spring probe contact to form part of a wafer probe. The pluggable contact is simply a wire or probe inserted into the plated hole to make electrical contact with the cap.

In another embodiment, the vertical feed through structure includes a tile with feed through holes, one end of each hole permanently encapsulating an electrical probe contact, and another end of each hole supporting a pluggable or detachable electrical contact element. The permanent probe contact is formed into a hole as part of the tile by injection molding or otherwise forming the substrate material around the probe. As with the cap in the first embodiment, the substrate can be an organic material such as epoxy, or a ceramic material such as LTCC or HTCC. The pluggable contact is formed by molding a sacrificial material formed in the shape of the pluggable contact into the substrate at the time of encapsulation of the permanent contact element. The sacrificial material is then etched away allowing the pluggable contact to be inserted. Indentations in the substrate and corresponding protrusions from the pluggable contact serve to lock the contact in place once inserted. Alternatively a spring retainer clip can be formed using the sacrificial material to hold the pluggable contact.

A decoupling capacitor can be provided in a pluggable contact enabling the decoupling capacitor to be plugged in in close proximity to a vertical feed through. The close proximity of a decoupling capacitor to the vertical feed through limits the size of decoupling capacitor needed, and the complexity of components for connecting the capacitor to the feed through.

### BRIEF DESCRIPTION OF THE DRAWINGS

Further details of the present invention are explained with the help of the attached drawings in which:

FIGS. 1A-1D show cross-sectional views of a substrate illustrating processing steps of a first method of manufacturing plated through holes;

FIG. 2 illustrates interconnect elements which may be attached to the plated through holes made using the process shown in FIGS. 1A-1D to form a space transformer for a probe assembly;

FIGS. 3A-3C show how an interconnect element is formed by a thin wire inserted into the plated through holes made using the process shown by FIGS. 1A-1D;

FIGS. 4A-4D show cross-sectional views of a substrate illustrating processing steps of a second method of manufacturing plated through holes with a thin wire inside;

FIGS. 5A-5E show cross-sectional views of a substrate illustrating processing steps of a third method of manufacturing plated attachment wells;

FIGS. 6-7 illustrate attachment of interconnect probes in the plated attachment wells made using the process shown in FIGS. 5A-5E;

FIGS. 8A-8B show an alternative configuration for manufacturing a plated attachment well to support a probe without the need for soldering;

FIGS. 9A-9E show cross-sectional views illustrating processing steps for manufacturing encased twisted tube springs that can be used as a layer for electrically interconnecting two other substrate layers;

FIG. 10 illustrates a first embodiment of a tile removably connectable to an interconnecting space transformer layer;

FIG. 11 shows modification to the cap used in the tile of FIG. 10;

FIG. 12 shows a tile with components as illustrated in FIGS. 10-11 having a plurality of insert caps making contact with probes of a second space transformer layer, as well as a power supply pin for carrying power to a power plane of the tile;

FIGS. 13A-13C show cross-sectional views illustrating manufacture of a second embodiment of a tile with a pluggable contact;

FIG. 14 shows alternative configurations for the permanent contact element and pluggable contact elements shown manufactured in FIGS. 13A-13C;

FIG. 15 shows a cross-sectional view showing a first substrate layer with the vertical feed through, as shown in FIG. 14, along with a decoupling capacitor; and

FIGS. 16A-16B show cross-sectional views illustrating a process for manufacturing a substrate with a spring clip in a cavity for better securing the decoupling capacitor mounted as illustrated in FIG. 15.

### DETAILED DESCRIPTION

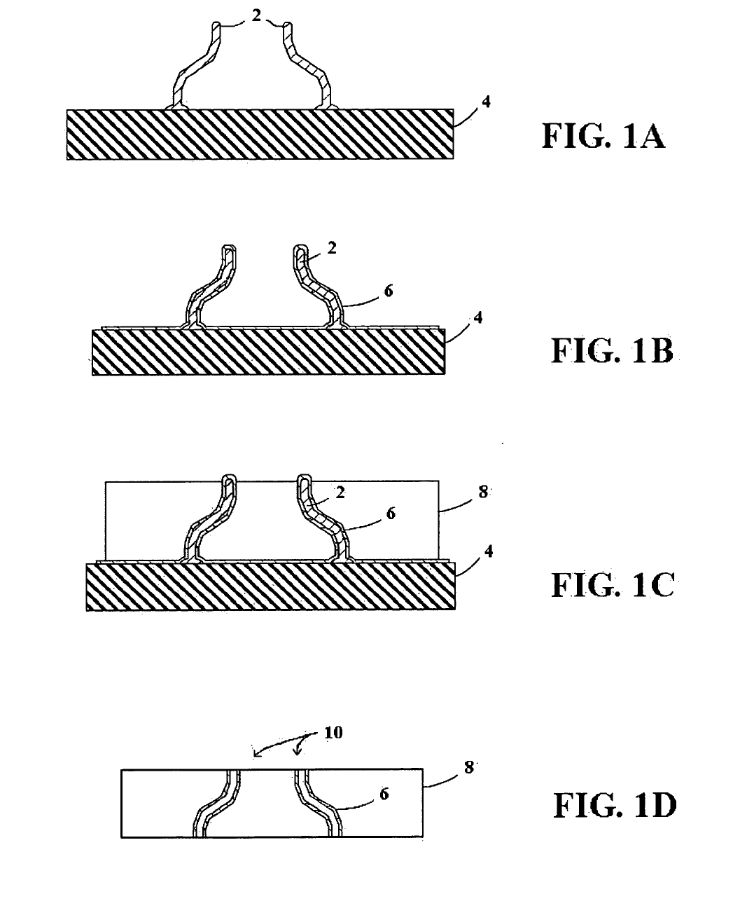

FIGS. 1A-1D show cross sectional views illustrating steps of a first method of making a substrate with plated through holes, where the plated through holes may be curved. In a first step shown in FIG. 1A, wires 2 are bonded to a first sacrificial substrate 4. The wires 2 may be bonded using standard wire bonding techniques, such as soldering or thermosonic bonding. The wires 2 are preferably made of a material that is readily etched or dissolved (e.g., copper, gold, aluminum). The wires are curved if curved plated through holes are desired, or straight if straight plated through holes are desired.

The first sacrificial substrate 4 can be formed using any number of desirable substrate materials. Examples of suitable substrate materials include silicon, ceramic, Iron/Nickel alloys (e.g., “alloy 42,” “Kovar,” “CuInvarCU”), etc. To facilitate eventual release of the structures to be formed on the first sacrificial substrate 4, its surface can be coated with a release layer, which may be a material that is readily etched away. Suitable release materials include copper, gold, aluminum and titanium-tungsten, but are not limited by these examples. The surface of the first sacrificial substrate 4 may also be coated with a material that facilitates bonding the wires 2 to its surface. Such materials include, for example, gold, palladium or silver. The coating which serves to facilitate bonding can likewise serve to form a redistribution layer, similar to copper on a printed circuit board (PCB). With a redistribution layer exposed after the sacrificial substrate 4 has been etched away, components can be attached to the coating or solder bumps can be placed in a fixed pattern. This gives the possibility of a second redistribution layer including: 1) where coated wires or probes are attached to the coating to connect to the second layer, and 2) where traces are deposited to connect to a second layer.

As shown in FIG. 1B, the wires 2 are coated with a durable plating material 6 such as rhodium or palladium. Traces can be used as a mask to etch the wire-coating layer to connect to other components. Any deposition method may be used, including electroplate, chemical vapor deposition, sputter deposition, electrolysis plating, electron beam deposition, or thermal evaporation. If electroplating is used, it may be desirable first to short the wires 2 together. This may be done in a variety of ways including (1) applying a layer of conductive material (a shorting layer) to the surface of the first sacrificial substrate, if the sacrificial substrate is not conductive in the first place, and then bonding the wires to the shorting layer, or (2) providing connections from each wire through the first sacrificial substrate (e.g., through vias in the substrate) to a shorting layer applied to the back side of the first sacrificial substrate 6. If the second of these two methods is used, the plating material 6 will form only on the wires 2 but not on the surface of the first sacrificial substrate 4.

The plating 6 shown in FIG. 1B assumes that a shorting layer was applied to both the surface of the first sacrificial substrate and the wires bonded to the shorting layer. The plating thus forms on the wires and over the entire surface of the first sacrificial substrate. As an alternative, masking material can be placed over selected areas of the shorting layer, preventing the plating from forming where the masking material is placed. The masking material can be used to pattern traces, which are formed in combination with the plated wires to connect the wires 2 to additional redistribution layers as described previously.

As will be seen, the wires 2 will be etched away, leaving a tube formed of the plating material 6. Alternatively, the wires can be pulled out in a separate operation after the coating is removed. To increase the inner diameter of this tube, one or more intermediate etchable layers, may be formed on the wire prior to application of the final plating material that will form the tube. The intermediate etchable layers will then be etched away with the wires 2. Alternatively, thicker wires can be used.

As shown in FIG. 1C, the plated wires are then encased in a final dielectric substrate material 8. Examples of material usable for the substrate 8 include (1) an epoxy that sets into a relatively hard, durable form, (2) a ceramic material like LTCC and HTCC, or (3) a glass material, etc. The dielectric can have its surface metalized by applying a coating using a known technique such as Chemical Vapor Deposition (CVD). The entire substrate can be electroplated with for example with nickel or a nickel alloy. The bulk substrate can then be grounded and used for impedance control.

Next, as shown in FIG. 1D, the first sacrificial substrate 4 is removed, and the top and bottom of the resulting structure are planarized, such as by polishing, lapping, grinding etc. Etching is then performed to remove the wires 2 leaving the plated material to form plated through holes 10. Planarizing the top is done enough to remove a portion of the plating 6 to expose the etchable wire material 2, so that the wire material 2 can be etched away. Planarizing the bottom can be done to remove the portion of the plating material 6 originally on the surface of substrate 4. Alternatively, rather than planarize the entire bottom surface, selected portions of the plating 6 on the bottom surface of the substrate 4 may be etched so that the through holes are not shorted together. Of course, if a masking material was applied to the structure shown in FIG. 1A between the wires 2 prior to plating, then the plating 6 shown in FIG. 1B would not have formed where the masking material was disposed, and the wires (and resulting through holes shown in FIG. 1D) would not be shorted together.

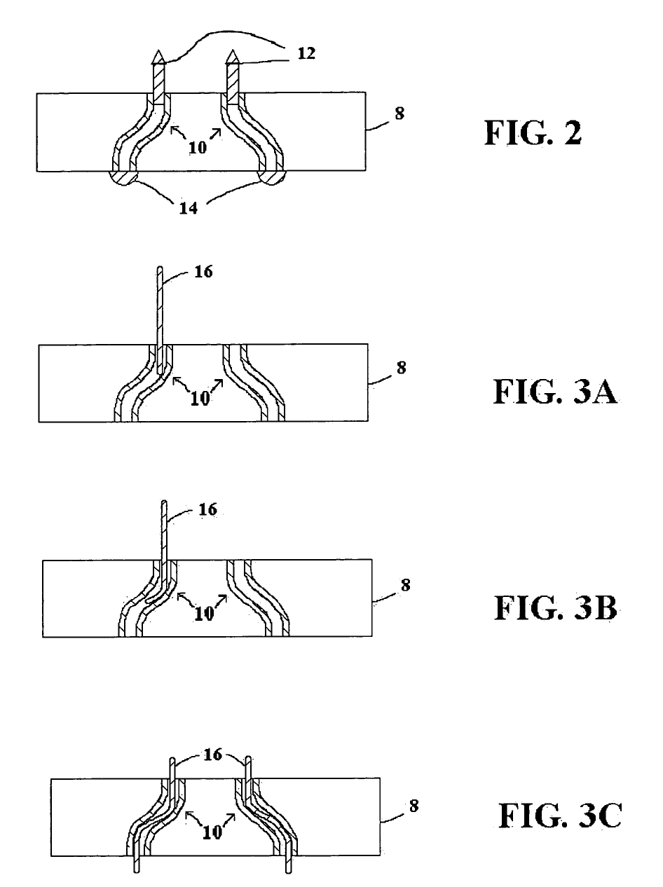

FIG. 2 shows a cross sectional view of the substrate 8 with plated through holes 10 formed by the process of FIGS. 1A-1D, illustrating examples of how interconnect elements, such as rods or probes, can be attached. As shown in FIG. 2, ends of interconnect elements in the form of electrically conductive rods or probes 12 are inserted in and secured (e.g., by soldering) to the plated through holes 10. Such insertable interconnect elements 12 may be rigidly attached to another device, such as by soldering, to form a connector. The interconnect elements 12 can also be resilient elements such as needle probes, cobra probes, or spring probes used to make components of a probe card assembly for probing electronic devices, such as on semiconductor wafers.

Nonlimiting examples of spring probes which may be used for the interconnect element 12 are shown in U.S. Pat. Nos. 5,994,152 and 6,255,126, U.S. Published Application No. U.S. 2001/0044225 A1, and pending U.S. patent application Ser. No. 10/202,712, filed Jul. 24, 2002, all of which are incorporated herein by reference. Although the spring probes shown in some of these illustrative examples, such as U.S. Pat. No. 6,255,126, are not cylindrical to permit insertion into the cylindrical openings in the plated through holes 10 shown in FIG. 2, plated through holes with other shapes could be formed as would be understood by a person of skill in the art. For example, the cylindrical wires 2 used in the steps of FIGS. 1A-1E can be replaced by square rods to enable the resulting plated through holes formed to match the square spring elements described in U.S. Pat. No. 6,255,126. Likewise wires with other geometrical shapes can be used to create plated through holes of a similar shape depending upon the shape of the interconnect element used.

Additional interconnect elements 14 may also be formed on the other side of the substrate. In the example shown in FIG. 2, the interconnect elements 14 are solder balls deposited over the plated through holes 10. Rod or probe interconnect elements 12 may be likewise inserted in place of the solder balls 14 to provide resilient contacts on both surfaces of substrate 8.

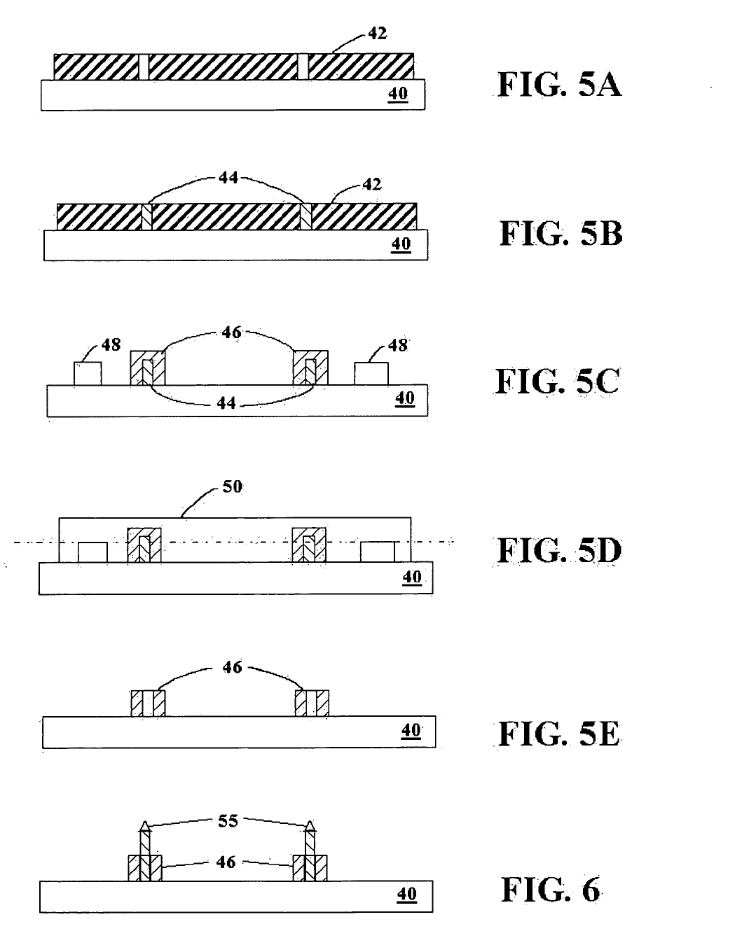

With resilient probes 12 attached to one side of the substrate 8 and solder balls 14 on the other (as shown in FIG. 2), a space transformer is formed which can be used in a probe card assembly to directly connect to a semiconductor wafer or other device under test. The structure of FIG. 2 can, thus, replace the space transformer 506 in FIG. 5 of U.S. Pat. No. 5,974,662, which is incorporated herein by reference. With resilient probes contacts attached to both sides of a substrate (not shown in FIG. 2), an interposer, such as the interposer 504 of a probe card assembly shown in FIG. 5 of U.S. Pat. No. 5,974,662, can be formed. One or more structures like the one shown in FIG. 2 may be secured to a larger substrate to build up a large array of probes, such as the tile 600 attached to a space transformer 622 in FIG. 6A of U.S. Pat. No. 5,806,181, incorporated herein by reference.

FIGS. 3A-3C illustrate an additional interconnect element configuration which may be used with the substrate 8 having plated through holes 10 formed by the process shown in FIGS. 1A-1D. FIGS. 3A-3C show how thin wires 16 are inserted into the plated through holes 10 of substrate 8. In FIG. 3A, the thin wire 16 is inserted into one of the plated through holes 10 only to a point where the plated through hole curves. The wire can be attached using solder similar to the rods or probes of FIG. 2. With curved plated though holes, the thin wire 16 can be inserted farther into the curved plated through hole 10, as shown in FIG. 3B, so soldering may not be required because friction with the walls of the through holes 10 may be sufficient to hold the thin wire 16 in place. If it is desirable to have thin wire probes extending from both sides of a substrate, the thin wire 16 can be extended farther through the plated through hole 10, as shown in FIG. 3C. Again, if the plated through hole is curved, friction will hold the thin wire, so soldering may not be required.

The wires 16 may form buckling beam (or “cobra”) type probes, with the substrate being a probe head, space transformer, or tile for a probe card. For buckling beam probes, the wires 16 are made of a resilient material so that they bend when contact is made with another electrical element, and then straighten out, or return to their original shape when disconnected. Because the plated through holes 10 provide added current carrying capacity, the wires 16 may be thinner than prior buckling beam probes. For example, such wires may have diameters less than 0.003 inches and in some embodiments 0.002 inches, 0.001 inches, or even smaller, while prior buckling beam probes required diameters of at least 0.003 inches.

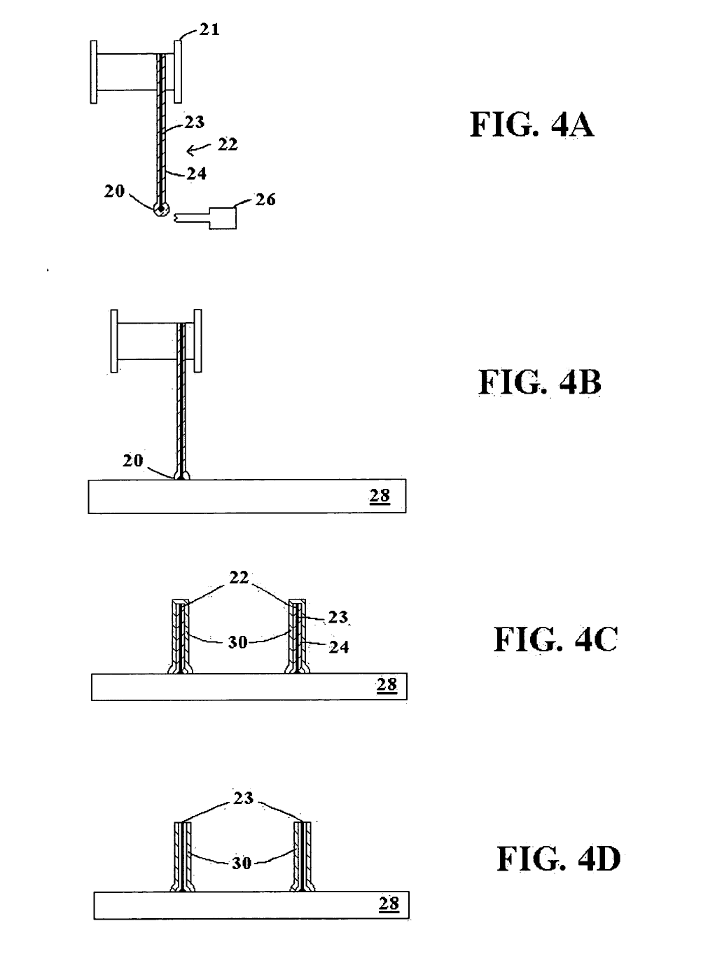

FIGS. 4A-4D illustrate a method of making a plated through hole with a thin fiber inside. As shown in FIG. 4A, a ball 20 is formed at the end of a wire 22 on a spool 21. The wire 22 comprises a thin fiber 23 (e.g., graphite) coated with a readily etched material layer 24 (e.g., copper, gold, aluminum). An electro-flame off tool 26, for example, may be used to cut the wire 22 to create the ball 20. As shown in FIG. 4B, the ball 20 is then bonded to a substrate 28 using standard wire bonding techniques. Alternatively, the wires may be simply cut or sheared without forming a ball, and the wired bonded directly to the substrate 28.

Wires 22 attached to the substrate 28 are next plated with a durable plating material 30 such as rhodium or palladium, as shown in FIG. 4C. Grinding or polishing is then performed to remove a portion of the plating material 30 to expose a portion of the etchable material coating layer 24. The etchable material layer 24 on the fiber 23 is then etched away, leaving the fiber 23 in a plated through hole tube formed by the durable plating material 30, as shown in FIG. 4D. All of the etchable material coating 24 may be etched away, as shown in FIG. 4D, leaving the fiber 23 loose in the tube of plating material 30. Alternatively, a portion of the coating near the bottom of the tube of plating material 30 may be left in place to better secure the fiber 23 inside the tube 30.

The tube of plating material 30 can be bent or curved, causing an end of the wire 23 to “pop” out of the end of the tube 30. The wire may be then more readily attached to form a coaxial type connector with an air core. Alternatively, the fiber 23 can have multiple coatings, only one of which will be readily etchable, so that after etching a wire will be provided within multiple tubes.

As an alternative to using a wire 22 made up of a thin fiber 23 coated with a readily etchable material layer 24, as described with respect to FIGS. 4A-4D, the wires 22 used in the process can be made entirely of an etchable material. As such, all of the wires 22 will be entirely etched away in the process leaving only plated through hole tubes 30 standing on a substrate 28.

FIGS. 5A-5E illustrate a method of making a plated attachment well. As shown in FIG. 5A, a substrate 40 is coated with a masking material 42 having openings. The openings are filled with a sacrificial fill material 44, as shown in FIG. 5B. The substrate 40 may form the surface of an electronic component, e.g. a space transformer, probe head, or tile for a probe card. As shown in FIG. 5C, the masking material 42 is next removed, and the sacrificial fill material 44 is plated with a durable plating material 46. Grinding stops 48 may optionally be attached to the substrate 40. As shown in FIG. 5D, a casting material 50 is applied. The casting material 50 is then ground (or polished or lapped or otherwise ground down) to the grinding stops 48 (if attached), as illustrated by the dashed line in FIG. 5D. After grinding the casting material 50, the grinding stops 48 are removed and the sacrificial fill material 44 is etched away, leaving the plating material forming attachment wells, as shown in FIG. 5E.

Rather than use grinding stops 48, a grinding machine may simply be configured to grind to a specified height above the electronic component surface or to grind a specified distance into the casting material. The grinding stops 48 may be any material that can be sensed by the grinding machine, and the casting material 50 can be any material that will support the plated sacrificial fill material during grinding and then can be readily removed (e.g., hard waxes, polymers, etc.).

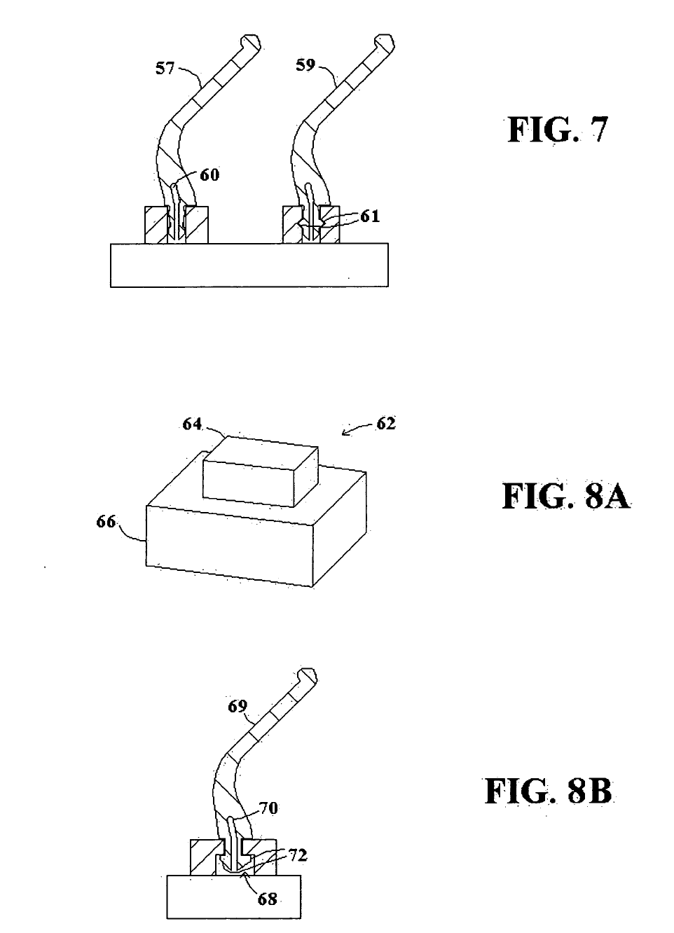

FIGS. 6-7 illustrate exemplary uses of the substrate with attachment wells formed using the method described with respect to FIGS. 5A-5E. In FIG. 6, rods or probes 55 are inserted and attached, e.g., by soldering to the attachment wells 46. FIG. 7 shows above surface wire type spring probes 57 and 59, which can be inserted in the attachment wells. The spring probe 57 has a slot 60 forming a compressible contacting surface when inserted within the well to securely hold the probe 57 within the well. Even with the compression slot 60, soldering can be used to assure the probe 57 remains engaged within the well. Probe 59 shows modification to the probe 57 to add laterally protruding bumps 61 as an alternative to assure the probe remains engaged within the well. Other alternative wire-type probes may be formed by bonding wires inside the wells. For example, the wire shown in FIGS. 7A-7C of U.S. Pat. No. 5,467,211 can be bonded inside the well. Optionally, the wire can be coated as shown in FIG. 8 of U.S. Pat. No. 5,467,211, incorporated herein by reference. When any of the wire-type probes are inserted, the well can be filled with solder to increase the strength of its attachment if desired.

The sacrificial fill material used to form the attachment wells in FIGS. 5A-5E can have a shape other than cylindrical. The fill material can be square, rectangular, etc. As a further alternative illustrated by the drawing in FIG. 8A, stacked structures of sacrificial fill material 62 can be formed by depositing and masking multiple layers 64 and 66. The structure of FIG. 8A includes the rectangular layers 64 and 66, the smaller 64 being stacked on top the larger 66.

The sacrificial fill structure 62 of FIG. 8A is used to form an attachment well 68 as shown in FIG. 8B, allowing a surface spring 69 to be attached without the need for soldering. The spring probe 69 includes a compressible slot 70 and lateral extension bumps 72. The extension bumps 72 extend into the large rectangular area, and engage the smaller rectangular area to prevent the spring probe 69 from being easily removed after insertion in the attachment well 68.

Probes or wires can be inserted into the attachment wells or plated through holes either one at a time, or together in a group fashion. For example, although only a single probe 69 is shown in FIG. 8, multiple spring probes such as probe 69 can be held in a fixture which aligns the probes for insertion into separate attachment wells, enabling the group of probes to be inserted into attachment wells concurrently. Even without snapping the probes into attachment wells as in FIG. 8, a fixture can hold groups of probes or wires in wells or holes while solder or epoxy is applied to secure the probes or wires concurrently. With support provided by the attachment wells or holes, groups of probes can potentially be transferred into the attachment wells or holes concurrently without requiring a holding fixture for the probes. Probes or wires can be installed in single or group fashion into the attachment wells or holes described herein, including the attachment wells formed as shown in FIGS. 5A-5E, or the plated through holes formed as shown in FIGS. 1A-1D. Wires or probes installed in a single or group fashion can include probes 12 of FIG. 2, wire 16 of FIGS. 3A-3C, probes 55 of FIG. 6, probes 57 and 59 of FIG. 7, or probe 69 of FIG. 8B.

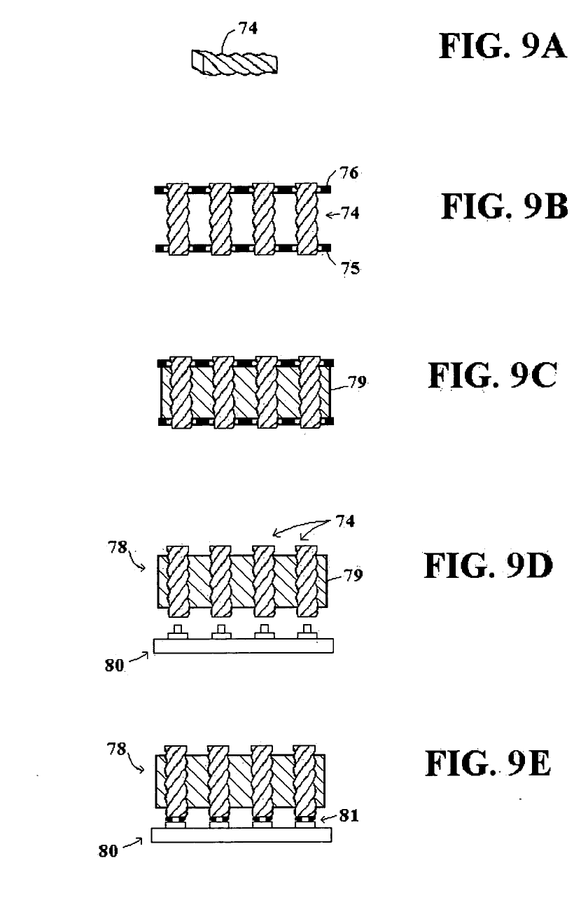

FIGS. 9A-9E show cross-sectional views illustrating processing steps for manufacturing encased twisted tube springs that can be used as a layer for electrically interconnecting two other substrate layers. In a first step shown in FIG. 9A, copper wires 74 with a square or rectangular cross section are twisted to a specific twist pitch. The copper wires are then plated using a hard and highly electrically conductive alloy such as rhodium. The coated wires are then cut to length.

As shown in FIG. 9B, a set of brass stencils 75-76 are used to align the twisted wire rods 74. The base or bottom stencil 75 can be used as a key for the start of the twists if the wires are not separately twisted before insertion into the stencils 75 and 76. A portion of the twisted rods 74 extend outside each stencil. After the twisted rods are inserted in the stencils 75-76, the gap between the brass stencils is filled with epoxy 79 by molding a solid epoxy, or injecting the epoxy in liquid form around the twisted wires, as shown in FIG. 9C.

As illustrated in FIG. 9D, the copper wire material and brass stencils 75 and 76 are next dissolved leaving the hollow rhodium twisted tubes encased in epoxy. The rhodium tube springs and epoxy layer now forms a layer 78 which can be used to interconnect other layers. With the tubes aligned in a pattern by the brass stencils, the tubes of layer 78 can be aligned to match probe locations on another substrate, as illustrated in FIG. 9D. FIG. 9E further shows the layer 78 with twisted tubes connected to mate with probes provided in attachment wells on a separate layer 80 having attachment wells with probes as shown in FIG. 6. As shown in FIG. 9E, to connect the layers 78 and 80, the probes on the layer 80 are inserted into the twisted tubes and can be attached using solder joints 81.

The ability to rework a tile layer which supports spring probes (reworking meaning to remove the tile and replace it with another tile) is very difficult to accomplish if soldering or epoxy connects the tile layer and an interconnecting space transformer layer to make permanent contacts between the layers. Probes are typically formed and attached by solder or epoxy to ceramic substrates to form tiles. The tiles are then attached to another multiplayer ceramic substrate space transformer using a thin film copper polyamide epoxy layer.

Reworking to remove a tile from a space transformer is further made difficult if an underfill material (such as a teflon or silicon gel) is used as a seal to fill gaps between a connected tile and space transformer. The under fill material is used to absorb stress and prevent cracking of the connecting thin film epoxy layer which can be under stress since during fabrication the rate of thermal expansion of the ceramic and epoxy layers is quite different. The difference in the coefficient of thermal expansion between the tile supporting the probes and the multiplayer space transformer can cause a significant misalignment. The curved plated through holes shown fabricated in FIGS. 1A-1D can help alleviate the misalignment problem, along with the underfill material. With different expansion rates between tile and space transformer layers, the process of permanently joining the tile layer to the space transformer layer is challenging and typically requires expensive x-ray procedures to inspect.

The difficulty with removing permanently connected tiles and space transformer layers is similar to the difficulty in disconnecting individual spring probes from tiles, since the spring probes must typically be directly attached with solder or an epoxy film to assure the probes remain robust. One solution to making the probes more easily removable is to use the spring contact probe and attachment well combination shown in FIG. 8B. A plug and unplug alternative to soldering or epoxying a tile to a space transformer is described to follow.

The ability to plug and unplug a tile from a space transformer is attractive for a number of reasons:
(1) The tiles could be pretested and yielded prior to commitment to an outgoing product;
(2) The tiles would be field replaceable; and
(3) The space transformer could be reused.
   The figures and description to follow describe procedures for manufacturing a tile, which can be plugged and unplugged from a space transformer. The manufacturing procedures are likewise applicable to other vertical feed through structures used to interconnect layers.

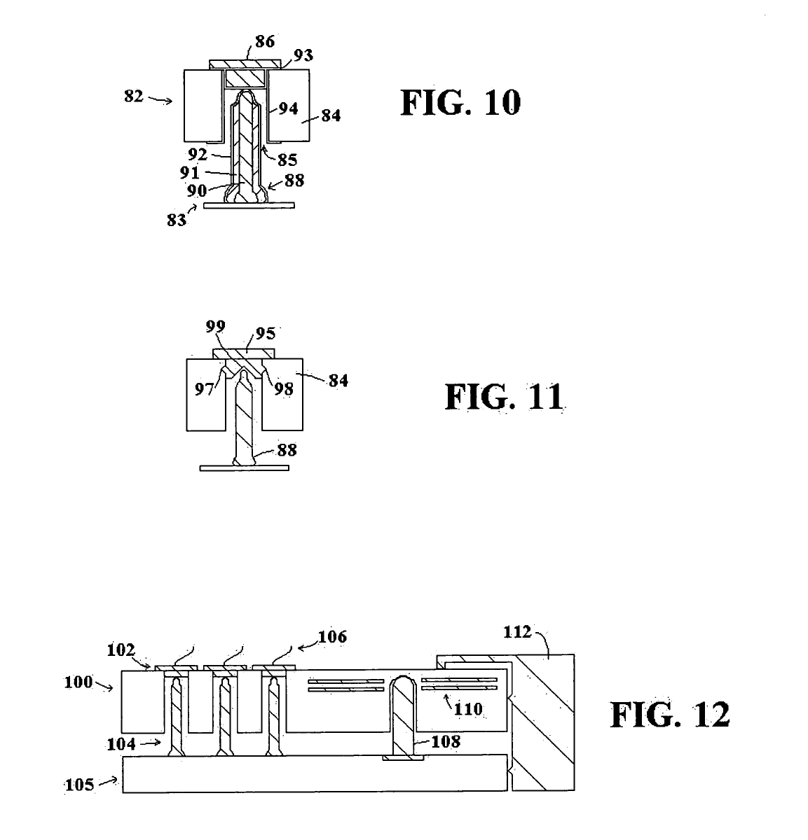

FIG. 10 shows a cross-sectional view illustrating a first embodiment of a tile 82 removably connectable to an interconnecting space transformer layer 83. In FIG. 10, the tile 82 is formed by a substrate 84 having a plated through hole 85, one end of the plated through hole 85 having an insert cap 86 providing an electrical contact and another end of the hole available for insertion of a probe 88 provided on the space transformer layer 83.

The insert cap 86 is permanently formed into a hole 85 as part of the tile 82 by one of a number of procedures including bonding, plugging in, or soldering. For example, the insert cap 86 can be bonded into the substrate 84 to form tile 82 by injection molding dielectric material around the insert cap 86. The dielectric material for the substrate 84 can be for example an organic material such as a an epoxy, or Novalac. The insert cap 86 can further be plugged into a sheet of plastic or green sheet ceramic forming the dielectric substrate 84 by hot pressing, cold pressing, vacuum lamination, or isostatic pressing the cap insert 86 into the substrate material 84. The insert cap 86 can further be epoxied into a hole in the substrate 84 after the hole 85 is either formed in the material or drilled in, such as by laser drilling. Although a single insert cap 86 is shown, multiple such insert caps can be inserted into dielectric material either one at a time or concurrently using a holding fixture, or dielectric can be formed around the insert caps.

If the green sheet ceramic material is fired after insertion of multiple insert caps 86, it is desirable that the position of the caps does not move in an x-y plane parallel to the plane of the space transformer layer 83 so that the insert caps 86 will align with the probes 88 of the space transformer 83 in an array environment. A green sheet of ceramic includes a ceramic powder encased in a liquid crystal polymer (LCP) or plastic fill material. The green sheet can be a high temperature cofired ceramic (HTCC), which is fired to as high as 1000° C. to burn away the LCP and form a ceramic substrate. The green sheet can also be a low temperature cofired ceramic (LTCC), which is fired at approximately 400° C. to burn away the LCP material and form a ceramic.

The probe 88 shown is a resilient spring probe, although in another embodiment a non-resilient probe could be used. The probe 88 shown in cross section includes an center gold wire 90 surrounded by a layer of nickel or palladium cobalt 91, which is then surrounded by another gold layer 92. The insert cap 86 is shown to be plated with a gold layer 93 along with gold plating 94 provided on the substrate 84 forming the plated through hole 85 to facilitate a good electrical bond between the cap 86, plated through hole 85, and probe 88.

FIG. 11 shows modification of the insert cap 86 of FIG. 10 to form an improved cap 95 to better assure the cap 95 remains permanently inserted in the substrate. As shown, the cap 95 includes lateral bump extensions 97-98 configured to engage the sides of the substrate 84. FIG. 11 further shows an alternative embodiment wherein plating is not provided in the hole of the substrate 84, electrical contact being maintained by connection of the cap 95 and the probe 88. The cap 95 of FIG. 11 further shows one embodiment where an indentation 99 is provided within the cap 95 to assure the tip of probe 88 contacts the center of the cap 95.

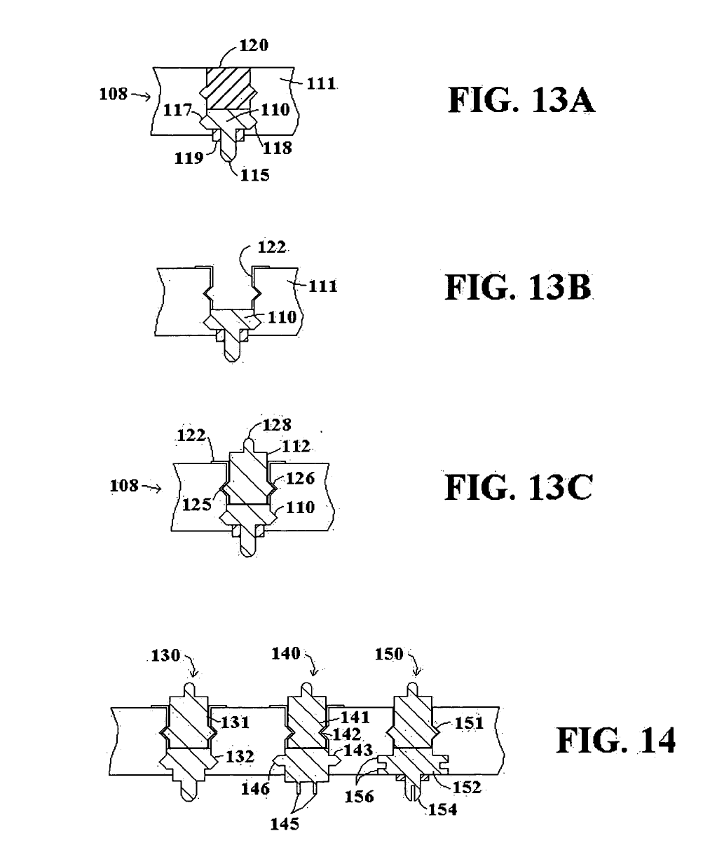

FIG. 12 shows a tile layer 100 with a plurality of insert caps 102 making contact with probes 104 of a second space transformer layer 105. The insert caps 102 and probes 104 are configured as described with respect to FIGS. 10 and 11, although the insert caps 102 are shown supporting spring contacts 106 to enable contact with pads on another substrate, such as an integrated circuit on a wafer for testing purposes. The spring probe contact can be manufactured and provided in the insert caps 102, similar to the spring probes that are provided in attachment wells shown in FIG. 7 and FIG. 8B.

FIG. 12 further shows the space transformer layer 105 including a power pin supply 108 for carrying power to a power plane on the tile 100. The power supply pin 108 further serves to align the tile 100 and space transformer layer 105. The tile layer 100 is further shown to include capacitive decoupling layers 110. A spring clip 112 is further shown for maintaining contact between the tile 100 and space transformer layer 105 once the layers are plugged together.

FIGS. 13A-13C show cross-sectional views illustrating manufacture of a second embodiment of a tile with a pluggable contact. The tile 108 formed by the process shown in FIGS. 13A-13C includes a vertical feedthrough with a first portion of the feedthrough including a permanent electrical contact 110, and another the other end having a pluggable or detachable electrical contact element 112 as shown in FIG. 13C.

Initially to form the tile 108, as shown in FIG. 13A, a permanent electrical contact element 110 is provided in a dielectric substrate 111. As with the embodiment of FIG. 10, the contact element 110 can be inserted into the substrate by one of a number of procedures including bonding, plugging in, or soldering as described with respect to FIG. 10. As with the dielectric of FIG. 10, the dielectric substrate 111 can be an organic material such as epoxy, or a ceramic material such as LTCC or HTCC. The contact element 110 is an electrically conductive material and includes a probe 115 for electrically contacting components on another substrate. The contact further includes lateral protrusions 117 and 118 serving to lock the contact element within the dielectric. A registration sleeve 119 serves to hold the overall contact element in a desired location within the substrate 111 during manufacture and provides a reference for planarizing the substrate 111. A sacrificial etchable material 120 is provided in a hole opposite the contact element 110 to enable forming an opening for a pluggable contact. Although a single permanent electrical contact 110 and sacrificial element 120 are is shown in FIG. 13A, multiple electrical contacts 110 and sacrificial elements 120 can be formed in a substrate 111 concurrently in a group fashion in a similar manner.

FIG. 13B shows that the sacrificial material 120 is next etched away. The permanent contact element 110 remains in place. In one embodiment, plating material 122 is deposited on one surface of the substrate 111 coating the region where the sacrificial material 120 was removed. Masking and etching are used to remove plating 122 significantly beyond the opening to prevent shorting with other contacts in an array structure.

FIG. 13C illustrates insertion of the pluggable contact element 112. Indentations 125 and 126 in the substrate and corresponding lateral protrusions 125 and 126 from the pluggable contact 112 serve to hold the contact 112 in place. Although a single pluggable contact element 112 is shown, multiple pluggable contact elements can be supported by a fixture and plugged into multiple substrate openings concurrently.

FIG. 14 shows alternative configurations for the vertical feedthrough formed by the permanent contact element and pluggable contact elements shown manufactured in FIGS. 13A-13C. The vertical feed through 130 includes a pluggable element 131 provided in a plated through hole identical to element 112 of FIG. 13C. Permanent contact 132 is likewise similar to the permanent contact 110, except that the registration sleeve 119 is provided integral to the rest of the contact element. The vertical feedthrough 140 includes a pluggable element 141 similar to the pluggable element 112 of FIG. 13C, except that indentations 142 are provided in the pluggable element 141, while the substrate includes protrusions to hold the pluggable element 141 in place. The permanent element 143 has dual probes 145 forming a two-pronged plug, while the remainder of the permanent element 143 has a uniform diameter with lateral protrusions 146 preventing the contact element 143 from being removed. The feedthrough 150 includes a pluggable element 151 identical to the pluggable element 112 of FIG. 13C, except the insert hole is not plated. The permanent element 152 includes a probe 154 with a slot cut to enable compression of the probe when connected. The permanent element 152 further includes two protruding disks 156 to strongly attach the permanent element to a substrate.

FIG. 15 shows a cross-sectional view of a substrate layer 160 with the vertical feedthrough 150, as shown in FIG. 14, along with a decoupling capacitor 166, the substrate 160 shown aligned to connect with a second substrate 162. As shown the probe 154 of the vertical feedthrough mates with a plated through hole 164 in the second layer 162. A connection line 174 is provided in the second layer 162 for connecting the probe 154 in plated through hole 164 to plated holes 170 and probes 168 of the decoupling capacitor 166. The probes 168 are permanently attached to the substrate and locked in place with regions 171 laterally protruding from the probes 168. Registration rings 172 are provided on the probes 168 as well as the probe 154 to enable alignment of components when the ceramic tile is formed. The configuration shown allows the decoupling capacitor 166 to be placed in close proximity to the probe 150 to minimize the size of capacitor needed as well as the complexity of connection for the decoupling capacitor 166.

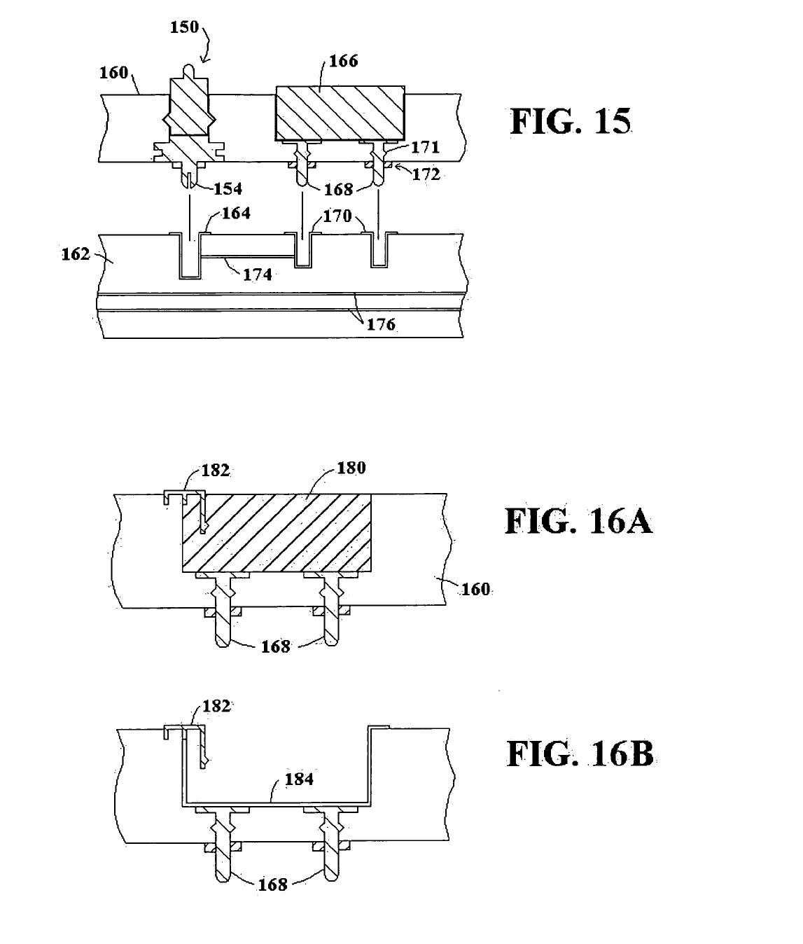

FIGS. 16A-16B show cross-sectional views illustrating a process for manufacturing a substrate with a spring clip 182 in a cavity provided for better securing the decoupling capacitor mounted as illustrated in FIG. 15. In the step shown in FIG. 16A, the permanently attached probes 168 have been formed in the substrate 160, and a sacrificial material 180 is provided in the opening for the capacitor with an opening forming the spring clip 182. The spring clip 182 is deposited on the sacrificial material 180 and masked to remove any excess plating. The sacrificial material 180 is then etched away as shown in FIG. 16B, leaving the spring clip attached to the substrate. Plating 184 is then provided in one embodiment to make electrical contact between the probes 168 and spring clip 182. Insertion of the capacitor 166 will compress the spring clip 182 to secure the decoupling capacitor 166 within the cavity and to assure electrical contact with the probes 168. Note that although the slot and spring clip are described for holding a capacitor, connector probes or other discrete elements such as a resistor or inductor can be inserted and held in place by the spring clip 182.

Although the present invention has been described above with particularity, this was merely to teach one of ordinary skill in the art how to make and use the invention. Many additional modifications will fall within the scope of the invention, as that scope is defined by the following claims.

1. A method of manufacturing a vertical feed through in a substrate comprising:
providing an electrical contact cap in a hole in a substrate, wherein the cap extends partially into the hole and partially outside the hole, wherein a portion of the hole is open for insertion of a probe on a second substrate to electrically contact the probe with the cap in the hole.

2. The method of claim 1 wherein the step of providing an electrical contact cap in a hole of the substrate comprises heating the substrate made up of a green sheet of ceramic to form a ceramic material around the cap.

3. The method of claim 2, wherein the cap is pressed into the hole formed in the green sheet prior to heating.

4. The method of claim 1 wherein the cap includes an opening with a resilient spring probe inserted in the opening.

5. The method of claim 1 further comprising plating at least a portion of the hole with an electrically conductive material.

6. The method of claim 1 wherein the cap comprises a laterally protruding portion extending into the substrate to hold the cap within the substrate.

7. The method of claim 1 wherein the cap comprises a first cylindrical region extending outside the substrate having a greater diameter than a second cylindrical region provided in the hole of the substrate, wherein a laterally protruding regions extend from the second cylindrical region to secure the cap within the substrate.

8. A method for manufacturing a vertical feed through in a substrate comprising:
stacking a first electrical contact and a sacrificial element to enable forming a feed through path;
forming a dielectric material making up the substrate around the first electrical contact and the sacrificial element;
removing the sacrificial element; and
plugging a second electrical contact element into an opening left by the sacrificial element to electrically contact the first electrical contact.

9. The method of claim 8 wherein the step of forming a dielectric material comprises inserting the first electrical contact and the sacrificial element into a hole provided in a green sheet ceramic and heating the green sheet to form a ceramic material.

10. The method of claim 8, wherein the first electrical contact comprises a first portion provided in the hole of the substrate and a second portion extending outside the substrate supporting a probe.

11. The method of claim 10, wherein the probe includes a slot enabling the probe to be spring compressed.

12. The method of claim 10, wherein the first portion includes a portion protruding laterally into the dielectric material to secure the first contact within the hole.

13. The method of claim 10, wherein the first portion includes an indentation for engaging a protrusion from the dielectric material to secure the first contact within the hole.

14. The method of claim 8, wherein the second electrical contact comprises a first portion for engaging the hole in the substrate and a second portion for extending outside the substrate supporting a probe.

15. The method of claim 8, wherein the second electrical contact element comprises a decoupling capacitor.

16. The method of claim 15 further comprising providing a spring clip attached to the substrate to engage the decoupling capacitor to secure the decoupling capacitor within the hole.

17. The method of claim 16 further comprising the step of forming the spring clip in an opening of the sacrificial material prior to removing the sacrificial material.

18. A substrate comprising:
a dielectric layer with a hole extending through the dielectric layer; and
a first electrical contact having a first portion provided in the hole of the substrate securely encapuslated by the substrate and a second portion extending outside the substrate.

19. The substrate of claim 18, wherein the dielectric layer is formed from a green sheet of ceramic.

20. The substrate of claim 18 further comprising:
a second electrical contact comprising a first portion provided in the hole electrically connecting to the first electrical contact, and a second portion for extending outside the substrate supporting a probe, wherein the first portion of the second electrical contact includes an engaging element for securing the second electrical contact within the hole of the dielectric.
